(19) United States
(12) Patent Application Publication
(10) Pub. No.: US 2008/0110399 A1
(43) Pub. Date: May 15, 2008

(54) ATOMIC LAYER DEPOSITION APPARATUS

(75) Inventors: Hyung-Sang Park, Seoul (KR); Dae Youn Kim, Daejeon (KR); Akira Shimizu, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM Genitech Korea Ltd., Cheonan-si (KR)

(21) Appl. No.: 11/936,630

(22) Filed: Nov. 7, 2007

(30) Foreign Application Priority Data
Nov. 9, 2006 (KR) 10-2006-0110553

(51) Int. Cl. C23C 16/00

(52) U.S. Cl. 118/715; 427/248.1

(57) ABSTRACT

A reactor configured to subject a substrate to alternately repeated surface reactions of vapor-phase reactants is disclosed. The reactor includes a reaction chamber, one or more inlets, and an exhaust outlet. The reaction chamber includes a reaction space. The reactor also includes a gas flow control guide structure within the reaction chamber. The gas flow control guide structure resides over the reaction space and is interposed between the inlets and the reaction space such that a laminar flow is generated in the reaction space. The gas flow control guide structure includes one or more channels. Each of the channels extends from a respective one of the inlets to a first portion of a periphery of the reaction space. Each of the channels defines a flow path extending from the respective one of the inlets to the reaction space. The gas flow control guide structure further includes a passage or shortcut formed through the gas flow control guide structure to provide a minority flow directly over the reaction space to merge with the laminar flow. This configuration allows films deposited on a substrate to have a uniform thickness, even in cases where reactants that are unstable at a deposition temperature is used.

### CROSS-REFERENCE TO RELATED APPLICATIONS

This application claims priority to and the benefit of Korean Patent Application No. 10-2006-0110553 filed in the Korean Intellectual Property Office on Nov. 9, 2006, the entire contents of which are incorporated herein by reference. This application is related to U.S. Pat. No. 6,539,891, issued on Apr. 1, 2003, entitled CHEMICAL DEPOSITION REACTOR AND METHOD OF FORMING A THIN FILM USING THE SAME. This application is also related to U.S. Patent Application Publication No. 2006/0249077 published on Nov. 9, 2006, entitled ATOMIC LAYER DEPOSITION APPARATUS, the disclosure of which is incorporated herein by reference.

### BACKGROUND OF THE INVENTION

1. Field of the Invention

The present invention relates to an apparatus for growing thin films on a surface of a substrate. More particularly, the present invention relates to an apparatus for producing thin films on a surface of a substrate by subjecting the substrate to alternately repeated surface reactions of vapor-phase reactants.

2. Description of the Related Art

In manufacturing semiconductor devices, various apparatuses and processes have been developed to provide a high quality thin film on a substrate. Several methods have been used to form a thin film, employing surface reaction of a semiconductor substrate. The methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Epitaxy (ALE). ALE was studied extensively for semiconductor deposition and electroluminescent display applications, and has been more recently referred to as Atomic Layer Deposition (ALD) for the deposition of a variety of materials.

ALD is a method of depositing thin films on a surface of a substrate through a sequential introduction of various precursor species to the substrate. The growth mechanism tends to rely on the adsorption of a first precursor on the active sites of the substrate. Conditions are such that no more than a monolayer forms, thereby self-terminating the process. Exposing the substrate to the first precursor is usually followed by a purging stage or other removal process (e.g., a “pump down”) wherein any excess amounts of the first precursor as well as any reaction by-products are removed from the reaction chamber. The second precursor is then introduced into the reaction chamber at which time it reacts with the first precursor and this reaction creates the desired thin film. The reaction terminates once all of the available first precursor species adsorbed on the substrate has been reacted. A second purge or other removal stage is then performed which rids the reaction chamber of any remaining second precursor or possible reaction by-products. This cycle can be repeated to grow the film to a desired thickness. The cycles can also be more complex. For example, the cycles may include three or more reactant pulses separated by purge or other removal steps.

In typical ALD processes, reactants are pulsed into a reaction space while the temperature of the reaction space is maintained within a certain range. The temperature range may be in an ALD window above the condensation temperatures of the reactants and below the thermal decomposition temperatures of the reactants. A thin film is formed by saturative surface reactions. Typically, a thin film having a uniform thickness may be formed on the surface of a substrate regardless of the surface roughness of the substrate. A thin film formed by an ALD process has relatively less impurities, and has relatively high quality. One of the recognized advantages of ALD over other deposition processes is that it is self-saturating and uniform as long as the temperature is within the ALD window and sufficient reactant is provided to saturate the surface in each pulse. Thus, neither temperature nor gas supply needs to be perfectly uniform in order to get uniform deposition.

A lateral or horizontal flow ALD reactor has been proposed. In a lateral flow ALD reactor, gases flow laterally or horizontally over and parallel to the top surface of a substrate. In such a lateral flow ALD reactor, flows of the gases are relatively fast and simple. Thus, high speed switching of gas supplies can be achieved, thereby reducing time for sequentially supplying process gases, and thus increasing throughput. Such increased speed is important because ALD process is inherently slow by comparison to PVD or CVD. An exemplary lateral flow ALD reactor has been disclosed in U.S. patent application Ser. No. 11/429,533, published as U.S. Publication No. 2006-0249077 A1 on Nov. 9, 2006, the disclosure of which is incorporated herein by reference.

FIG. 1 illustrates an exemplary lateral flow ALD reactor. The reactor includes a reactor cover 100, a first inlet 110 for introducing a first reaction gas and/or inert gas, a second inlet 112 for introducing a second reaction gas and/or inert gas, and an exhaust outlet 120. As denoted by arrows, a first gas supplied through the first inlet 110 travels through a gap between an upper gas flow control plate 140 and the reactor cover 100. Then, the first gas turns downward. Next, the first gas flows laterally through a gap between a lower gas flow control plate 142 and a substrate 150. The first gas is then exhausted through the exhaust outlet 120. A second gas supplied through the second inlet 112 travels through a gap between the upper gas flow control plate 140 and the lower gas flow control plate 142. Then, the second gas turns downward. Next, the second gas flows laterally through the gap between the lower gas flow control plate 142 and the substrate 150, and is then exhausted through the exhaust outlet 120.

The above information disclosed in this Background section is only for enhancement of understanding of the background of the invention and therefore it may contain information that does not constitute the prior art that is already known in this country to a person of ordinary skill in the art.

### SUMMARY OF THE INVENTION

The instant disclosure has been made in an effort to provide an atomic layer deposition apparatus for depositing thin films. In certain embodiments, the ALD apparatus can be used with reactants that are unstable at a deposition temperature.

In one embodiment, an atomic layer deposition (ALD) reactor includes a reaction chamber comprising a reaction space. The reaction space includes a first point. The reactor also includes one or more inlets configured for communicating with a reactant; an exhaust outlet; and a gas flow control guide structure between the one or more inlets and the reaction space. The gas flow control guide structure comprises a channel extending from one of the inlets to a first portion of a periphery of the reaction space. The channel defines part of a first flow path extending from the inlet to the first point within the reaction space. The reactor further includes a substrate holder positioned to expose a supported substrate to the reaction space. The gas flow control guide structure further includes a passage formed through the gas flow control guide structure. The passage is configured to fluidly communicate the reactant from one of the inlets to the first point within the reaction space. The passage defines at least part of a second flow path extending from the one of the inlets to the first point. The second flow path is shorter than the first flow path.

In another embodiment, an atomic layer deposition (ALD) reactor comprises: a reactor cover comprising one or more inlets and an exhaust outlet; and a reactor base comprising a substrate holder. The reactor base and the reactor cover are configured to define a reaction chamber. The reaction chamber comprises a reaction space. The reaction space comprises an upstream periphery and a downstream periphery positioned on the opposite side from the upstream periphery. The reactor further comprises one or more gas flow control plates positioned within the reactor chamber. Each of the gas flow control plates at least partially defines an inflow channel configured to guide a reactant supplied through one of the inlets to the upstream periphery of the reaction space. At least one of the gas flow control plates defines one or more passages penetrating through the gas flow control plate. The passages are configured to open into the reaction space between the upstream and downstream peripheries thereof.

In yet another embodiment, an atomic layer deposition (ALD) reactor comprises: a reaction chamber comprising a reaction space. The reaction space comprises an upstream periphery and a downstream periphery positioned on the opposite side from the upstream periphery. The reactor also includes a first injection port in fluid communication with a reactant source. The first port is configured to supply a first portion of a reactant from the reactant source. The first port is configured to define a first flow path including a first portion extending laterally from the upstream periphery to the downstream periphery of the reaction space. The reactor further comprises a second injection port in fluid communication with the reactant source. The second port is configured to supply a second portion of the reactant. The second port is configured to define a second flow path merging with the first flow path at a point downstream of the upstream periphery of the reaction space.

In yet another embodiment, a method of depositing a reactant on a substrate in a reaction space which comprises an upstream periphery and a downstream periphery is provided. The method comprises a plurality of atomic layer deposition cycles, each comprising: supplying a reactant to the reaction space at a first vertical level. Supplying the reactant comprises supplying a first portion of the reactant via a first path and a second portion of the reactant via a second path shorter than the first path. Supplying the first portion of the reactant comprises in sequence: flowing the first portion outwardly and horizontally at a second vertical level toward the upstream periphery of the reaction space, and flowing the first portion vertically to the upstream periphery and then horizontally into the reaction space. The first vertical level is different from the second vertical level. Each cycle further comprises reacting the reactant with a surface of the substrate; and removing excess reactant from the reaction space.

In yet another embodiment, a method of depositing a reactant on a substrate in a reaction space is provided. The reaction space comprises an upstream periphery and a downstream periphery. The method comprises a plurality of atomic layer deposition cycles, each comprising: supplying a first portion of a reactant into the reaction space such that a laminar flow of the reactant is generated from the upstream periphery to the downstream periphery over substantially the entire portion of a substrate in the reaction space; and supplying a second portion of the reactant vertically into the reaction space such that the second portion merges with the laminar flow of the reactant at a point downstream of the upstream periphery of the reaction space.

In yet another embodiment, a gas flow control guide structure for use in an atomic layer deposition (ALD) reactor comprises: a body including a top surface and a bottom surface. The body comprises a substantially horizontal channel extending generally in a direction from a generally central portion of the body to at least a portion of an edge of the body; and at least one through-hole penetrating the body, the through-hole opening through the bottom surface of the body. The through-hole is arranged to distribute a reactant across a dimension extending substantially perpendicular to the direction.

In another embodiment, a lateral flow atomic layer deposition (ALD) apparatus in which reactant gases flow in a gas flow direction substantially parallel to a surface of a substrate includes a substrate holder for supporting a substrate, a reactor cover configured to define a reaction space contacting the substrate holder, a gas inlet for inflowing of a process gas, a gas exhaust outlet, and a lower gas flow control plate disposed substantially parallel to the substrate in the reaction space and facing the substrate. The lower gas flow control plate defines a lateral flow path traversing the length of the substrate before reaching the gas exhaust outlet. The lower gas flow plate also has holes, and a portion of the process gas supplied through the gas inlet is supplied to a gap between the lower gas flow control plate and the substrate through the holes.

The relative restrictions to flow formed by the holes and the lateral flow path is such that amount of process gas supplied through the holes may be about 50% or less of the total amount of process gas supplied through the gas inlet. The lower gas flow control plate may have a trench formed on the upper side thereof, and the holes may be formed in the trench. The cross-section of the trench may be larger than that of the holes. The width of the holes may be about 2 mm or less. The gas inlet may be disposed in the upper part of the apparatus. The apparatus may include a plurality of gas inlets, and a portion of the process gas supplied to one gas inlet of the plurality of gas inlets may be supplied to the gap between the lower gas flow control plate and the substrate through the holes. The amount of process gas supplied through the holes may be about 50% or less of the total amount of process gas supplied through the one gas inlet.

The atomic layer deposition apparatus may further include an upper gas flow control plate, and the upper gas flow control plate may be configured to separate process gases supplied through the plurality of gas inlets from each other until the process gases supplied through the plurality of gas inlets arrive at the gap between the lower gas flow control plate and the substrate. The upper gas flow control plate may be disposed substantially parallel to the lower gas flow control plate.

The atomic layer deposition apparatus may include a plurality of groups of gas inlets, each group of gas inlets may be configured to supply one process gas. The process gas supplied to at least one inlet of one group of gas inlets may be supplied to the gap between the lower gas flow control plate and the substrate through the hole formed in the lower gas flow control plate. The amount of process gas supplied through the hole may be about 50% or less of the total amount of process gas supplied through the one group of gas inlets. The height of a gas flow space between the lower gas flow control plate and the substrate may be non-uniform across the direction perpendicular to the gas flow direction. The amount of process gas supplied through the hole may be about 50% or less of the total amount of process gas supplied through the gas inlet.

### BRIEF DESCRIPTION OF THE DRAWINGS

FIG. 1 is a schematic cross-sectional view of a conventional lateral flow ALD reactor.

FIG. 2 is a schematic top plan view illustrating a gas flow over a circular substrate in a lateral flow ALD reactor according to one embodiment.

FIG. 3 is a cross-section of a lateral flow ALD reactor according to one embodiment.

FIG. 4 is a perspective view of a lateral flow ALD reactor according to another embodiment.

FIG. 5 is a perspective view of one embodiment of a gas flow control plate of a lateral flow ALD reactor.

FIG. 6 is a cross-section of a lateral flow ALD reactor according to another embodiment.

FIG. 7A is a top plan view of another embodiment of a gas flow control plate of a lateral flow ALD reactor.

FIG. 7B is a cross-section of the gas flow control plate of FIG. 7A, taken along lines 7B-7B.

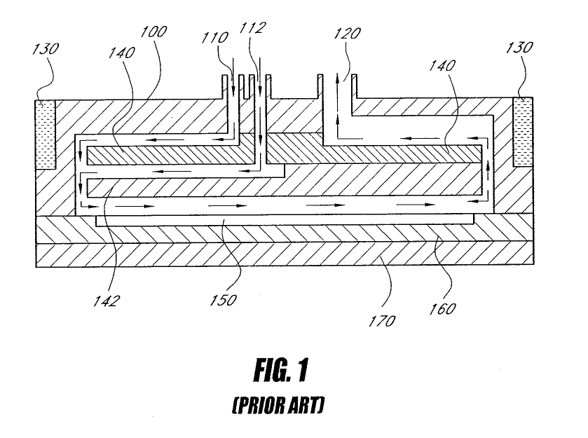

### DETAILED DESCRIPTION OF THE PREFERRED EMBODIMENT

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. While illustrated in the context of a particular type of lateral flow ALD reactor, having plates to define different flow paths, the skilled artisan will readily appreciate that the principles and advantages taught herein apply to other types of reactors. The multiple flow paths taught herein for one reactant gas have particular utility for unstable ALD reactants.

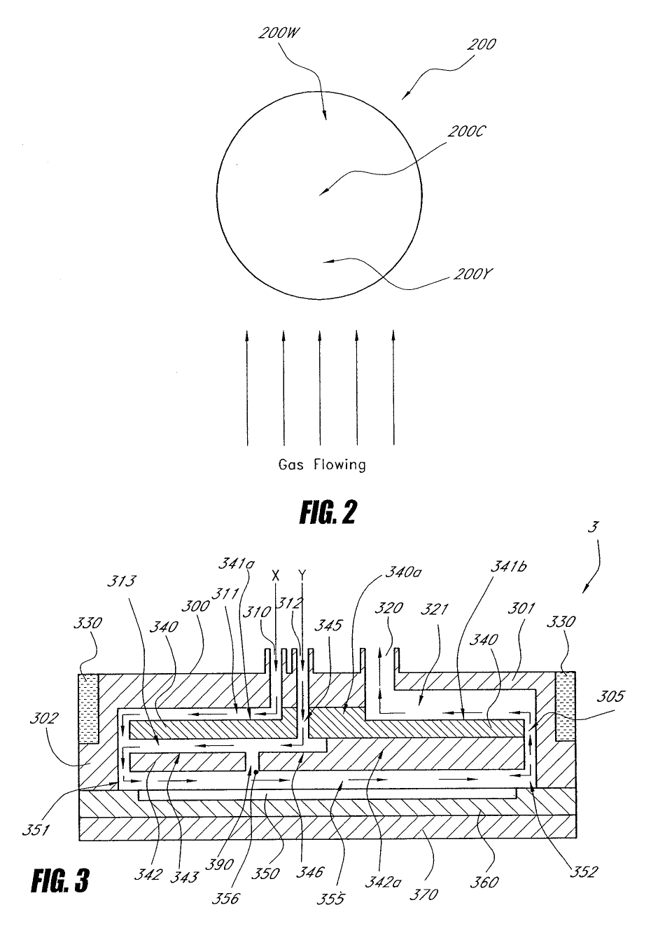

Typical atomic layer deposition processes use reactants that are stable at a deposition temperature. However, in some cases, reactants that are unstable at a deposition temperature may also be used. For example, ozone gas (O₃) introduced into the reaction space of a later flow ALD reactor may quickly break down and/or recombine to form oxygen gas (O₂) at a relatively high deposition temperature. Thus, the concentration of the ozone gas may be higher at the upstream of the reaction space than at the downstream of the reaction space. Accordingly, the concentration of ozone gas that reacts to leave oxygen on a substrate in such a lateral flow ALD reactor may not be uniform. Similar problems of early decomposition can occur with other reactants, such as organic and metal precursors. This problem will be described in detail with reference to FIG. 2.

FIG. 2 is a schematic top plan view illustrating a gas flow over a circular substrate in the reaction space of a lateral flow ALD reactor. In FIG. 2, the lateral flow ALD reactor itself is omitted, and only the substrate and the gas flow are shown schematically. In an instance where a reactant that is unstable at a deposition temperature is supplied into the reaction space, at least some portion of the reactant may be decomposed while traveling to and through the reaction space. Thus, the concentration of the reactant may vary widely depending on the position within the reaction space. For example, the concentration of the reactant may be higher at an upstream position 200Y than at an intermediate position 200C. The concentration of the reactant may be higher at the intermediate position 200C than at a downstream position 200W. For example, in an instance in which ozone gas is used at a deposition temperature of about 300° C., the concentration of the ozone gas over the substrate 200 at the position 200W may be substantially lower than that at the position 200Y.

Thus, when reactants are unstable at the deposition temperature, a resulting film deposited on a substrate will likely have a non-uniform thickness, unless pulse duration is so long that some of the reactant survives even to reach the downstream end of the substrate. Particularly, when a film is deposited on a substrate that has a non-planar surface having a plurality of protrusions and depressions (i.e., high surface area patterned substrate) in a lateral flow ALD reactor, it is likely that the resulting thin film has a non-uniform thickness, or pulse duration impractically long is used.

In one embodiment, an ALD reactor includes a reaction chamber and a gas flow control guide structure housed within the reaction chamber. The reaction chamber and the gas flow control guide structure together define a reaction space so as to produce a primary lateral or horizontal flow across the surface of a substrate in the reaction space. The gas flow control guide structure also defines inflow channels to guide gases from one or more inlets of the reaction chamber to the reaction space.

In one embodiment, the gas flow control guide structure may further include passages or shortcuts in the form of openings extending from at least one of the inflow channels to the reaction space. In other embodiments, the gas flow control guide structure may include direct passages from at least one of the inlets to the reaction space, bypassing the inflow channels. The shortcuts or passages provide a secondary flow directly over the substrate to merge with the primary laminar flow. These shortcuts increase the likelihood that even unstable reactants reach central and downstream portions of the substrate prior to reactant breakdown, ensuring better uniformity without high pulse duration.

Referring to FIG. 3, one embodiment of an ALD reactor will be described in detail. FIG. 3 is a cross-sectional view of an ALD reactor 3. In FIG. 3, arrows represent flows of reactants and exhaust gases within the reactor 3 during its operation. The illustrated ALD reactor 3 includes a reactor cover 300, a gas flow control guide structure 305, a first gas inlet 310, a second gas inlet 312, a gas exhaust outlet 320, a substrate holder 360, a cover heater 330, and a substrate heater 370. The substrate holder 360 and the substrate heater 370 together form at least part of a reactor base.

The lower surface of the gas flow control guide structure 305, the upper surface of the substrate holder 360, and a portion of the sidewall together define a reaction space 355. The reaction space 355 includes an upstream periphery 351 and a downstream periphery 352. A substrate 350 can be maintained in the reaction space 355, particularly on the substrate holder 360, during a deposition process. In one embodiment, a gap between the gas flow control guide structure 305 and the substrate 350 (i.e., the height of the reaction space 355) may be about 20 mm or less, particularly about 10 mm or less. In other embodiments, the gap between the gas flow control guide structure 305 and the substrate 350 may be relatively narrow to permit prompt switching of one reactant to another in the reaction space.

The reactor cover 300 forms an upper part of the reactor 3, and has a short cylinder-like structure with its top blocked. The reactor cover 300 includes a circular top plate 301 and a sidewall 302 extending from the periphery of the top plate 301. The sidewall 302 extends substantially perpendicular to the top plate 301.

The first and second gas inlets 310, 312, and a gas exhaust outlet 320 are formed through the top plate 301 of the reactor cover 300. The first and second gas inlets 310, 312 are in fluid communication with first and second reactant sources (not shown), respectively, through pipes (not shown). Preferably the reactants are suitable for ALD, though the skilled artisan will find appreciation for the principles taught herein for other types of vapor deposition. A cross-sectional area of the gas exhaust outlet 320 may be equal to or greater than a total of cross-sectional areas of the first and second gas inlets 310, 312.

The cover heater 330 surrounds a portion of the sidewall 302 of the reactor cover 300. The cover heater 330 serves to maintain the reactor 3 at a predetermined temperature.

The substrate heater 370 is positioned under the substrate holder 360. The substrate heater 370 may be integrally attached to the lower surface of the substrate holder 360. The substrate heater 370 serves to heat the substrate 350 to a predetermined temperature during a deposition process.

The illustrated gas flow control guide structure 305 includes an upper gas flow control plate 340 and a lower gas flow control plate 342. The upper gas flow control plate 340 is stacked over the lower gas flow control plate 342. A central portion of the upper gas flow control plate 340 is attached to an inner bottom surface of the reactor cover 300. In other embodiments, the gas flow control guide structure may further include additional gas control plates, depending on the number of reactants supplied into the reactor. The gas flow control plates 340 and 342 can be assembled into and detached from the reactor cover 300. This configuration allows easy maintenance and cleaning. In certain embodiments, however, the gas flow control guide structure may be integrally formed with the reactor cover 300 rather than having detachable gas flow control plates as described above. In still other arrangements, the multiple flow paths taught herein for a single reactant can be defined by completely different structures. The illustrated gas flow control guide structure defines a first inflow channel or passage 311, a second inflow channel or passage 313, and an outflow channel or passage 321. The first and second inflow channels 311, 313 each serve as primary flow paths and are configured to guide process gases separately from each other to the reaction space 355 along a primarily lateral flow path, parallel to and across a major surface of the substrate. In the illustrated embodiment, the reaction space 355 is positioned at a first vertical level while each of the channels 311, 313, 321 is positioned at a vertical level different from the first vertical level.

The upper gas flow control plate 340 has first and second grooves 341a and 341b. The first groove 341a defines the first inflow channel 311 with a portion of an inner bottom surface of the reactor cover 300 for a first reactant X supplied through the first inlet 310. The second groove 341b defines the outflow channel 321 with another portion of the inner bottom surface of the reactor cover 300 for excess reactant and reaction by-products. The upper gas flow control plate 340 also has a through-hole 345 vertically penetrating the upper gas flow control plate 340. The through-hole 345 is configured to be in fluid communication with the second inlet 312 and a groove 346 of the lower gas flow control plate 342 which will be described below. The upper gas flow control plate 340 may be formed of a metallic or ceramic material.

In certain embodiments where multiple gas flow control plates are employed, each of the gas flow control plates above the lowermost plate has at least one vertical through-hole as described above for feeding reactants through to grooves in lower gas flow control plates. In one embodiment where n number of plates are stacked over one another, an n-th plate from the bottom has n−1 through-holes. For example, where there are three stacked plates, a top plate (a 3rd plate from the bottom) has two through-holes, and a middle plate (a 2nd plate from the bottom) has one through-hole and one groove similar to the groove 346. In addition, a bottom plate has no through-holes for this purpose (there are other through-holes to form shortcuts, as described below) and one groove similar to the groove 346. In a plate having multiple through-holes for feeding lower grooves, the through-holes are positioned at horizontally different locations so that the inflow channels separately fluid-communicate with the inlets. In addition, the through-holes of the stacked plates are vertically aligned to allow fluid communication between the inflow channels and the inlets.

The upper gas flow control plate 340 also includes a solid part 340a between or around the grooves 341a and 341b. The solid part 340a forms sidewalls of the grooves 341a and 341b, and is configured to force the flow outward from the first inlet 310, around a plate periphery, through the reaction space 355, around another plate periphery, and inward to the exhaust outlet 320.

The lower gas flow control plate 342 has a groove 343. The groove 343 defines a second inflow channel 313 with a lower surface of the upper gas flow control plate 340 for a second reactant Y supplied through the second inlet 312. The groove 343 further extends to a central groove 346 of the lower gas flow control plate 342 so that the second inflow channel 313 is in fluid communication with the second inlet 312 via the through-hole 345 of the upper gas flow control plate 340. In addition, a lower surface of the lower gas flow control plate 342 and an upper surface of the substrate holder 360 define the reaction space 355 in which the substrate 350 will be processed. For embodiments providing an in-situ plasma in the reaction space 355, a gap between the lower gas flow control plate 342 and the substrate holder 360 can be adjusted to provide an optimal volume and electrode spacing for the reaction space 355. Preferably, the lower gas flow control plate 342 is formed of an insulating, e.g., ceramic material, and a metal electrode may be attached to the lower surface of the lower gas flow control plate 342. A skilled artisan will appreciate that the shapes and structures of the grooves of the gas flow control plates 340 and 342 may be varied, depending on the design of a reactor.

The lower gas flow control plate 342 also includes a solid part 342a around the grooves 343 and 346. The solid part 342a forms sidewalls of the grooves 343 and 346, forcing the flow outward from the second inlet 312, around a plate periphery, through the reaction space 355, around another plate periphery, and inward to the exhaust outlet 320 defined by the upper gas flow control plate 340.

The lower gas flow control plate 342 is shaped and sized to produce a primary laminar flow over the substrate 350. In the illustrated embodiment, the lower gas flow control plate 342 covers substantially the entire portion of the substrate 350. In addition, the bottom surface of the lower gas flow control plate 342 is substantially planar. When viewed from above, the lower gas flow control plate 342 may have a shape corresponding to the shape of the substrate 350. In one embodiment, the lower gas flow control plate 342 may have a square shape or a rectangle shape. In another embodiment, the lower gas flow control plate 342 may have a circular shape.

The lower gas flow control plate 342 also includes one or more holes 390 formed therethrough to provide shortcuts. The holes 390 are configured to provide a flow directly over the substrate 350, downstream of the substrate's leading edge. The holes 390 can open to a first point 356 within the reaction space 355. The illustrated first point 356 is positioned closer to the substrate's leading edge than the trailing edge. In other embodiments, the first point 356 can be positioned generally in a middle region between the substrate's leading and trailing edges. The flow merges with the laminar flow over the substrate 350. In the context of this document, a gap at the upstream periphery 351 of the reaction space 355 forms a first injection port for a reactant into the reaction space 355 while the holes 390 together form a second injection port for the reactant into the reaction space 355.

The illustrated holes 390 are configured to allow the second inflow channel 313 to be in fluid communication with the reaction space 355 through the lower gas flow control plate 342. The holes 390 may have a circular shape. In other embodiment, the holes 390 may have other shapes, for example, an elongated rectangular shape or a shape of a narrow strip. In an embodiment where the holes 390 have a circular shape, the diameter of the holes 390 may be about 2 mm or less. In another embodiment, the holes can be replaced by one or more narrow and elongated slit(s), where the width of the slit is about 2 mm or less. The holes 390 or slit(s) are configured to distribute a reactant in the reaction space 355 across a dimension generally perpendicular to the laminar flow.

In another embodiment, the first inflow channel 311 may also be configured to be in fluid communication with the reaction space 355 through the upper and lower gas flow control plates 340, 342 by way of shortcuts defining one or more secondary flow paths in addition to the primary lateral flow path that traverses the full length of the substrate. In such an embodiment, the upper and lower gas flow control plates 340, 342 may have holes configured to allow the first inflow channel 311 to be in fluid communication with the reaction space 355 at a central or downstream location. These holes are positioned laterally away from those of the holes 390 for connecting the second inflow channel 313 to the reaction space 355. In addition, the holes of the stacked plates 340, 342 are vertically aligned to allow a secondary, shortened flow path between the first inflow channel 311 and a central or downstream portion of the reaction space 355.

In other embodiments, a gas flow control guide structure may include more than two gas flow control plates defining a corresponding number of inflow channels. In such embodiments, a lowermost plate may have the same configuration as that of the lower gas flow control plate 342 of FIG. 3 to allow the lowermost inflow channel to be in fluid communication with the reaction space through the lowermost plate. In addition, one or more of other inflow channels overlying the lowermost inflow channel may also be configured to be in fluid communication with the reaction space through two or more of the plates underlying the inflow channel, as described above with respect to the first inflow channel 311.

Next, flows of reactants and exhaust gases within the reactor according to one embodiment will be described in detail with reference to FIG. 3. A first reactant X supplied through the first inlet 310 passes a gap between the reactor cover 300 and the upper gas flow control plate 340. The reactant X then turns downward along the sidewall 302 of the reactor cover 300, and flows horizontally over the substrate 350 through the gap between the lower gas flow control plate 342 and the substrate 350.

A second reactant Y supplied through the second inlet 312 travels horizontally through a gap between the upper gas flow control plate 340 and the lower gas flow control plate 342. A portion of the reactant Y continues to travel horizontally through the gap and reaches the sidewall 302 of the reactor cover 300. Then, the portion of the reactant Y turns downward along the sidewall 302 of the reactor cover 300. The portion of the reactant Y then flows horizontally over the substrate 350 through the gap between the lower gas flow control plate 342 and the substrate 350. This path defines a primary lateral flow path that traverses the entire substrate surface parallel thereto. Preferably a majority of reactant Y follows this primary path, as dictated by the relative restrictions along the primary and secondary flow paths.

Another portion of the reactant Y is supplied over the substrate 350 through the holes 390 of the lower gas flow control plate 342. The holes 390 provide a shortcut flow path such that the other portion of the reactant Y reaches a central or downstream portion of the substrate 350 in a relatively short period of time. For example, this configuration increases the concentration of an unstable reactant toward the downstream of the reaction space 355. In embodiments in which the decomposition rate of a reactant is high at a deposition temperature, the flow through the holes 390 allows the reactant to reach substantially the entire surface of the substrate 350 before being decomposed. The shortcut provided by the holes 390 defines a secondary flow path that merges with the primary flow path and traverses less than the entire length of the substrate.

In the illustrated embodiment, the portion of the reactant Y flowing through the holes 390 of the lower gas flow control plate 342 may form a minority flow while the laminar flow forms a majority flow. In other words, the portion of the reactant Y flowing through the holes 390 may be less than 50% of the total amount of the reactant Y supplied through the second inlet 312. Accordingly, the gas flow over the substrate 350 remains substantially horizontal, but a minority flows over only part of the substrate.

A method of depositing a film using the ALD reactor described above will be described below. First, a substrate 350 is loaded into the reaction space 355 of the reactor 3, particularly on the substrate holder 360.

A first reactant X is supplied through the first gas inlet 310 while an inert gas, e.g., argon (Ar) and/or nitrogen (N₂) gas, is supplied through the second gas inlet 312. During this step, the first reactant is adsorbed onto the substrate 350. Next, an inert gas, e.g., argon (Ar) and/or nitrogen (N₂) gas, is supplied through the first and second gas inlets 310 and 312 to purge an excess first reactant and any reaction by-products.

Subsequently, a second reactant Y is supplied through the second gas inlet 312 while an inert gas, e.g., argon (Ar) and/or nitrogen (N₂) gas, is supplied through the first inlet 310. In the illustrated embodiment, a portion of the second reactant (preferably a majority) traverses a primary flow path that laterally traverses the entire major surface of the substrate. Another portion (preferably a minority) of the second reactant traverses a second flow path that represents a shortcut to a central or downstream portion of the substrate, where the secondary flow path merges with the primary flow path. During this step, the second reactant reacts with the adsorbed species or fragments of the first reactant on the substrate 350. Next, an inert gas, e.g., argon (Ar) and/or nitrogen (N₂) gas, is supplied through the first and second gas inlets 310 and 312 to purge an excess second reactant and any reaction by-products. This single cycle typically forms less than one molecular monolayer of the material being deposited.

Then, if additional deposition is required, for example, to form a film having a desired thickness, the above cycle of steps is repeated a predetermined number of times. For example, the cycle is sequentially repeated tens or hundreds of times. Then, the deposition is completed.

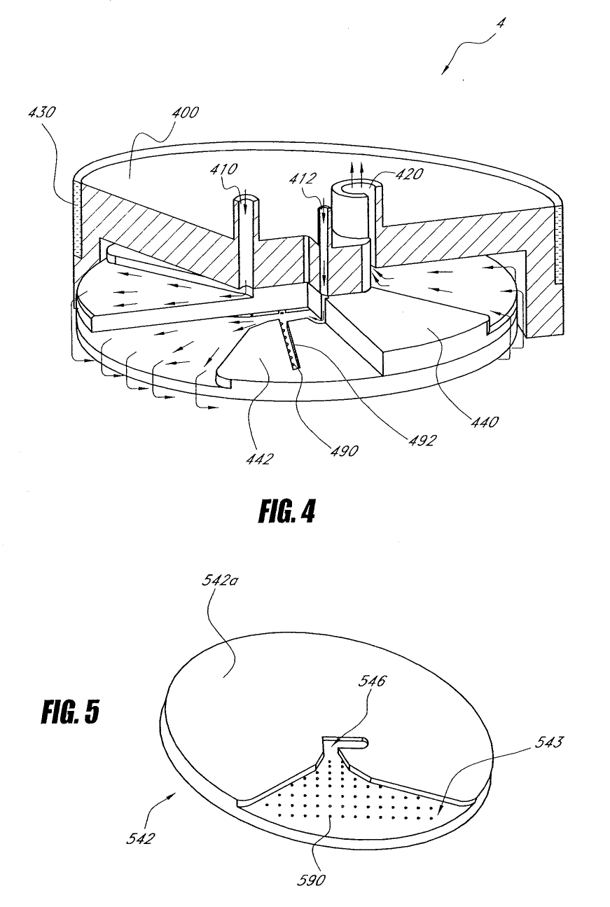

Referring to FIG. 4, an ALD reactor according to another embodiment will now be described. FIG. 4 is a perspective view of an ALD reactor 4 according to another embodiment. The configuration of the reactor 4 of FIG. 4 can be as described above with respect to that of the reactor 3 of FIG. 3 except that a lower gas flow control plate 442 includes a trench 492. The configurations of other elements of the reactor 4 can be as described above with respect to those of the reactor 3 of FIG. 3. Thus, the detailed description of the reactor is omitted.

As shown in FIG. 4, a trench 492 is formed on an upper portion of the lower gas flow control plate 442. In addition, a plurality of holes 490 penetrating through the lower gas flow control plate 442 are formed at the bottom of the trench 492. In the illustrated embodiment, the trench 492 has an elongated shape having a length and a width when viewed from above. In the context of this document, the length of an elongated shape refers to the longer dimension of the elongated shape while the width of the elongated shape refers to a dimension extending substantially perpendicular to the length. The width of the trench 492 may be substantially greater than the size of the holes 490.

In the illustrated embodiment, a substrate (not shown) is positioned under the lower gas flow control plate 442. A portion of a gas supplied through a second inlet 412 travels through the trench 492 and the holes 490, and then reaches the substrate. The cross-sectional area of the trench 492 is sufficiently large such that substantially the same amount of a gas can reach each of the holes 490, regardless of the positions of holes 490 relative to the second inlet 412. In other words, the holes 490 provide sufficient back pressure compared to the trench 492 that gas is evenly distributed.

In other embodiments, the width of the trench 492, and the sizes and positions of the holes 490 may vary widely depending on the reactor design. At least one of the size of each hole 490, the distance between the holes 490, and the width of the trench 492 may vary in accordance with the distance between each hole 490 and the second inlet 412.

In the illustrated embodiment, the plurality of holes 490 are aligned in a row at substantially the same interval. In other embodiments, holes 490 may be arranged to form a curved line such as an arc. The distances between the holes 490 may not be the same as one another. In certain embodiments, the holes 490 may be arranged in a plurality of lines.

The trench 492 may have substantially the same depth across the trench 492. In addition, the bottom surface of the lower gas flow control plate 442 opposite from the trench 492 may be substantially planar. This configuration allows the depths of the holes 490 to be substantially uniform, thereby permitting the amount of gas supplied through each hole 490 to be uniform.

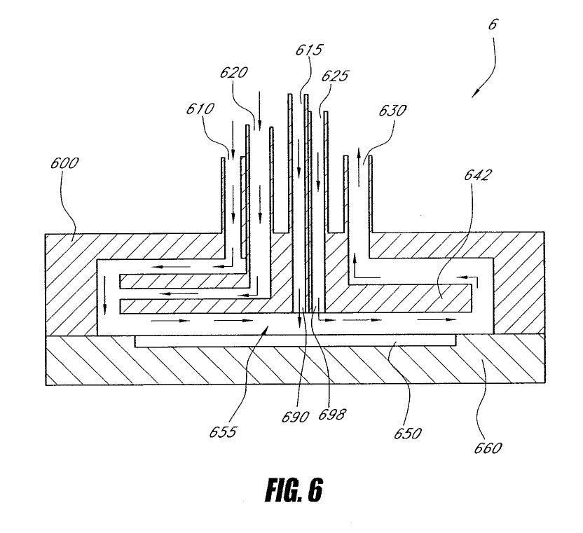

Referring to FIG. 5, another embodiment of a lower gas flow control plate of the ALD reactor will now be described below. The configurations of other elements that can be used with the lower gas flow control plate can be as described above with respect to those of the reactor 3 of FIG. 3. The lower gas flow control plate 542 has a groove 543 tapered toward its central portion. The groove 543 is in a form of a sector of a circle. The groove defines an inflow channel with a lower surface of an upper gas flow control plate (not shown) for a reactant supplied through the second inlet (not shown), as shown in FIG. 4. Referring back to FIG. 5, the groove 543 further extends to a central groove 546 of the lower gas flow control plate 542 so that the inflow channel is in fluid communication with the second inlet. A skilled artisan will appreciate that the shapes and structures of the grooves of the gas flow control plate 542 may be varied, depending on the design of a reactor.

The lower gas flow control plate 542 also includes a solid part 542a around the grooves 543 and 546. The solid part 542a forms sidewalls of the grooves 543 and 546, forcing the flow outward from the second inlet, around a plate periphery, through the reaction space, around another plate periphery, and inward to the exhaust outlet defined by the upper gas flow control plate.

In the illustrated embodiment, the lower gas flow control plate 542 also includes a plurality of holes or openings 590 formed within the groove 543. The holes 590 are distributed across substantially the entire portion of the groove 543. This configuration allows a portion of reactant to reach the substrate through the holes 590 through shortcut secondary flow paths, as described above with respect to FIG. 3, while maintaining a horizontal flow over the substrate. A skilled artisan will appreciate that the number and positions of the holes 590 can vary widely depending on the reactor design.

In the embodiments shown in FIG. 3 and FIG. 4, the reactor includes two gas inlets and two gas flow control plates. In another embodiment, an ALD reactor may include a single gas inlet and a single gas flow control plate such that all reactants are supplied through the single gas inlet sequentially. An exemplary reactor including a single gas inlet and a single gas flow control plate is disclosed in U.S. Pat. No. 6,539,891, issued on Apr. 1, 2003, entitled CHEMICAL DEPOSITION REACTOR AND METHOD OF FORMING A THIN FILM USING THE SAME, the disclosure of which is incorporated herein by reference. In such an embodiment, the reactor may include a single gas flow control plate having holes such that a portion of a reactant supplied through the gas inlet more quickly reach a central or downstream portion of a substrate in the reaction space, compared to the primary lateral flow, before merging with the primary flow and traversing the remainder of the substrate laterally.

Referring to FIG. 6, an ALD reactor 6 according to another embodiment will now be described. The reactor 6 includes a first inlet 610 and a third inlet 615, both of which are configured for supplying a first reactant. The reactor 6 also includes a second inlet 620 and a fourth inlet 625, both of which are configured for supplying a second reactant. The third inlet 615 and the fourth inlet 625 are formed through a lower gas flow control plate 642. The lower gas flow control plate 642 has holes 690 and 698 in fluid communication with the third inlet 615 and the fourth inlet 625, respectively. This configuration allows the third inlet 615 and the fourth inlet 625 to be in fluid communication with the reaction space 655 of the reactor 6. The configurations of other elements of the reactor 6 can be as described above with respect to those of the reactor 3 of FIG. 3.

Portions of the first and second reactants supplied through the first inlet 610 and the second inlet 620 horizontally flow over the substrate 650 via the sidewall of the reactor cover 600. These portions take a relatively long path. This primary flow path traverses the entire surface of the substrate 650 laterally, parallel to a major surface of the substrate 650. On the other hand, other portions of the first and second reactants supplied through the third inlet 615 and the fourth inlet 625 are supplied directly to a central or downstream portion of the substrate through the holes 690 and 698 of the lower gas flow control plate 642, taking a relatively short secondary path, which merges with the primary flow path and flows laterally over the remainder of the substrate 650. In the illustrated embodiment, the amount of the first reactant supplied through the first inlet 610 is substantially the same as or greater than that supplied through the third inlet 615. In other words, a portion of the first reactant supplied through the holes 690 of the lower gas flow control plate 642 may be about 50% or less of a total amount of the first reactant supplied to the reactor.

Similarly, the amount of the second reactant supplied through the second inlet 620 is substantially the same as or greater than that supplied through the fourth inlet 625. In other words, the portion of the second reactant supplied through the holes 698 of the lower gas flow control plate 642 may be about 50% or less of the total flow of the second reactant supplied to the reactor. This configuration allows the gas flow over the substrate 650 to be maintained substantially horizontal.

In one embodiment, the holes 690 and 698 may have a circular shape when viewed from above. The diameter of the holes 690 and 698 may be about 2 mm or less. In other embodiments, the holes can have an elongated shape. The width of the elongated holes may be about 2 mm or less. In the illustrated embodiment, the gap between the lower gas flow control plate 642 and the substrate 650 may be about 20 mm or less, and particularly, about 10 mm or less.

Another embodiment of a method of depositing a film using the atomic layer deposition reactor of FIG. 6 will now be described. First, a substrate 650 is loaded into the reaction space of the reactor, particularly on the substrate holder 660 of the reactor 6.

Then, a first reactant is supplied through the first and third gas inlets 610 and 615 while an inert gas is supplied through the second and fourth gas inlets 620 and 625. This allows the first reactant to be adsorbed onto a substrate 650. Next, inert gases are supplied through the first to fourth gas inlets 610, 620, 615, and 625 to purge an excess first reactant and any reaction by-products.

Subsequently, a second reactant is supplied through the second and fourth gas inlets 620 and 625 while an inert gas is supplied through the first and third gas inlets 610 and 615. This allows the second reactant to react with adsorbed species or fragments of the first reactant on the substrate 650. Next, inert gases are supplied through the first to fourth gas inlets 610, 620, 615, and 625 to purge the excess second reactant and any reaction by-products. Typically less than a monolayer is formed by the above described cycle. Then, if additional deposition is required, the above cycle of steps is repeated. The cycles can be sequentially repeated tens or hundreds of times. Then, the deposition is completed.

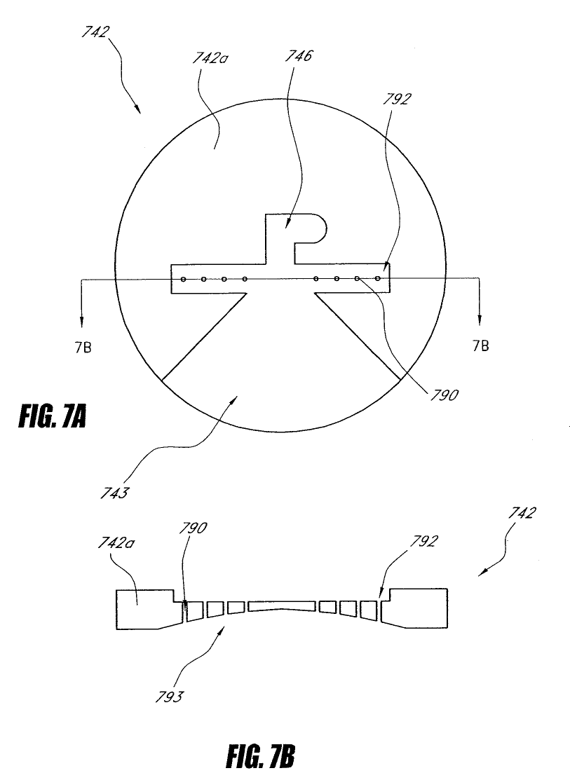

Referring to FIGS. 7A and 7B, another embodiment of a lower gas flow control plate for use in a similar reactor as FIG. 3 with an upper plate will now be described below. The illustrated lower gas flow control plate includes a groove 743 tapered toward its central portion. The groove 743 further extends to a central groove 746 of the lower gas flow control plate 742. The lower gas flow control plate 742 also includes a solid part 742a around the grooves 743 and 746. The solid part 742a forms sidewalls of the grooves 743 and 746, forcing the flow outward from the second inlet, around a plate periphery, through the reaction space, around another plate periphery, and inward to the exhaust outlet defined by the upper gas flow control plate.

The lower gas flow control plate 742 also includes a trench 792 in the solid part 742a between the groove 743 and the central groove 746. In addition, a plurality of holes 790 penetrating through the lower gas flow control plate 742 are formed at the bottom of the trench 792. The lower gas flow control plate 742 also includes a tapered portion or depression 793 on the opposite side of the plate 742 from the trench 792. This tapered portion 793 is depressed away from the substrate holder (not shown) within the ALD reactor. Thus, a reaction space defined partially by the lower gas flow control plate 742 includes a central region that is greater in height than other regions thereof. In other words, the substrate holder and the lower gas flow control plate 742 define a reaction space above the substrate that is not uniform in height across a direction perpendicular to the gas flow direction. In the illustrated embodiment, however, the reaction space is substantially uniform in height along the gas flow direction, forming a ceiling having a tubular or cylindrical shape. This configuration facilitates deposition on a substrate having a high surface area (e.g., greater than 50 times a planar substrate) which requires a longer gas supply duration and a larger amount of a reactant gas than a substrate having a planar surface.

In the embodiments described above, only two reactants are used for an ALD process. In certain embodiments, however, three or more reactants may be used for an ALD process. The three or more reactants may be supplied sequentially and cyclically into the reaction space, separated in time and space, using valves and separate inlets as described above. Preferably, during any given reactant pulse through one inlet, purge gas is provided through all other inlets. Preferably, all inlets are purged between reactant pulses. Plasma can optionally be employed during one or more of the reactant pulses. In an embodiment, some of the reactants may be simultaneously supplied, depending on the recipe in accordance with various variances on truly separated ALD reactions. In addition, a skilled artisan will appreciate that the reactors of the embodiments described above can be adapted to various other types of vapor deposition processes.

In the ALD reactors described above, a primary laminar flow of a reactant is provided over a substrate while a secondary flow of the same reactant is provided directly over the substrate, taking a shortcut before merging with the primary flow path. In one embodiment, the majority of the reactant takes the primary flow path while a minority of the reactant takes the secondary flow path. This configuration allows films deposited on the substrate to have a uniform thickness, particularly when using a reactant that is unstable at a deposition temperature.

Although various preferred embodiments and the best mode have been described in detail above, those skilled in the art will readily appreciate that many modifications of the exemplary embodiment are possible without materially departing from the novel teachings and advantages of this invention.

We claim:

1. An atomic layer deposition (ALD) reactor, comprising:
a reaction chamber comprising a reaction space, the reaction space including a first point;
one or more inlets configured for communicating with a reactant;
an exhaust outlet;
a gas flow control guide structure between the one or more inlets and the reaction space, the gas flow control guide structure comprising a channel extending from one of the inlets to a first portion of a periphery of the reaction space, wherein the channel defines part of a first flow path extending from the inlet to the first point within the reaction space; and
a substrate holder positioned to expose a supported substrate to the reaction space,
wherein the gas flow control guide structure further includes a passage formed through the gas flow control guide structure, the passage being configured to fluidly communicate the reactant from one of the inlets to the first point within the reaction space, the passage defining at least part of a second flow path extending from the one of the inlets to the first point, the second flow path being shorter than the first flow path.

2. The reactor of claim 1, wherein the gas flow control guide structure is configured to produce a laminar flow within the reaction space, the laminar flow starting at the first portion of the periphery of the reaction space and ending at a second portion of the periphery of the reaction space, the second portion being on the opposite side from the first portion, and wherein the first point is generally in a middle region between the first and second portions of the periphery of the reaction space.

3. The reactor of claim 1, wherein the gas flow control guide structure is configured to produce a laminar flow within the reaction space, the laminar flow starting at the first portion of the periphery of the reaction space and ending at a second portion of the periphery of the reaction space, the second portion being on the opposite side from the first portion, and wherein the first point is positioned closer to the first portion of the periphery of the reaction space than the second portion of the periphery of the reaction space.

4. The reactor of claim 1, wherein the channel is configured to supply a first amount of the reactant to the reaction space, wherein the passage is configured to supply a second amount of the reactant to the reaction space, and wherein the first amount is equal to or greater than the second amount.

5. The reactor of claim 1, wherein the passage is configured to allow the channel to be in fluid communication with the first point of the reaction space, and wherein the passage and a portion of the channel together form the second flow path.

6. The reactor of claim 5, wherein the gas flow control guide structure comprises a plurality of gas flow control plates stacked over one another, wherein each of the plurality of gas flow control plates defines a lower surface and sidewalls of a respective one of the plurality of channels, and wherein the passage is formed through at least one of the gas flow control plates.

7. The reactor of claim 6, wherein the plurality of gas flow control plates comprise a lowermost gas flow control plate including a top surface and a bottom surface, and wherein the passage is formed through the bottom surface of the lowermost gas flow control plate.

8. The reactor of claim 7, wherein the passage comprises a plurality of openings.

9. The reactor of claim 8, wherein the lowermost gas flow control plate further includes a trench on the top surface of the lowermost gas flow control plate, the trench extending from the channel defined by the lowermost gas flow control plate, and wherein the plurality of openings are formed within the trench.

10. The reactor of claim 8, wherein the plurality of openings are distributed across substantially the entire portion of the lower surface of the channel.

11. The reactor of claim 7, wherein the lowermost gas flow control plate further includes a depression on the bottom surface of the lowermost gas flow control plate.

12. The reactor of claim 1, wherein the one or more inlets comprise a first inlet and a second inlet, wherein the first inlet is in fluid communication with the reaction space via the channel, and wherein the second inlet is in fluid communication with the reaction space via the passage and via no channel.

13. An atomic layer deposition (ALD) reactor, comprising:
a reactor cover comprising one or more inlets and an exhaust outlet;
a reactor base comprising a substrate holder, the reactor base and the reactor cover being configured to define a reaction chamber, the reaction chamber comprising a reaction space, the reaction space comprising an upstream periphery and a downstream periphery positioned on the opposite side from the upstream periphery; and
one or more gas flow control plates positioned within the reactor chamber, each of the gas flow control plates at least partially defining an inflow channel configured to guide a reactant supplied through one of the inlets to the upstream periphery of the reaction space,
wherein at least one of the gas flow control plates defines one or more passages penetrating through the gas flow control plate, the passages being configured to open into the reaction space between the upstream and downstream peripheries thereof.

14. The reactor of claim 13, wherein one of the inflow channels and the passages are configured to be in fluid communication with the same reactant source, wherein the inflow channel is configured to supply a first amount of a gas from the reactant source to the reaction space, wherein the passages are configured to supply a second amount of the gas from the reactant source to the reaction space, wherein the first amount is equal to or greater than the second amount.

15. The reactor of claim 13, wherein the passages are configured to allow one of the inflow channels to be in fluid communication with the reaction space.

16. The reactor of claim 13, wherein the passages are configured to allow one of the inlets to be in direct fluid communication with the reaction space, bypassing the inflow channels.

17. An atomic layer deposition (ALD) reactor, comprising:
a reaction chamber comprising a reaction space, the reaction space comprising an upstream periphery and a downstream periphery positioned on the opposite side from the upstream periphery;
a first injection port in fluid communication with a reactant source, the first port being configured to supply a first portion of a reactant from the reactant source, the first port being configured to define a first flow path including a first portion extending laterally from the upstream periphery to the downstream periphery of the reaction space; and
a second injection port in fluid communication with the reactant source, the second port being configured to supply a second portion of the reactant, the second port being configured to define a second flow path merging with the first flow path at a point downstream of the upstream periphery of the reaction space.

18. The reactor of claim 17, wherein the second flow path extends from a region above the reaction space into the reaction space.

19. The reactor of claim 17, wherein the first flow path further comprises:
a second portion extending substantially vertically to the upstream periphery of the reaction space; and
a third portion extending substantially horizontally to the second portion of the first flow path.

20. The reactor of claim 17, further comprising a gas flow control guide structure configured to define the first and second flow paths within the reaction chamber.

21. A method of depositing a reactant on a substrate in a reaction space, the reaction space comprising an upstream periphery and a downstream periphery, the method comprising a plurality of atomic layer deposition cycles, each comprising:
supplying a reactant to the reaction space at a first vertical level, wherein supplying the reactant comprises supplying a first portion of the reactant via a first path and a second portion of the reactant via a second path shorter than the first path, and wherein supplying the first portion of the reactant comprises in sequence: flowing the first portion outwardly and horizontally at a second vertical level toward the upstream periphery of the reaction space, and flowing the first portion vertically to the upstream periphery and then horizontally into the reaction space, the first vertical level being different from the second vertical level;
reacting the reactant with a surface of the substrate; and
removing excess reactant from the reaction space.

22. The method of claim 21, wherein the first portion is equal to or greater in amount than the second portion.

23. The method of claim 21, wherein supplying the second portion of the reactant comprises in sequence: flowing the second portion horizontally at the second vertical level, and flowing the second portion vertically to the reaction space.

24. The method of claim 21, wherein supplying the second portion of the reactant comprises flowing the second portion vertically to the reaction space, and wherein supplying the second portion does not include flowing the second portion horizontally.

25. The method of claim 21, wherein the atomic layer deposition cycles are performed at a predetermined temperature, and wherein the reactant is at least partially decomposable at the predetermined temperature.

26. A method of depositing a reactant on a substrate in a reaction space, the reaction space comprising an upstream periphery and a downstream periphery, the method comprising a plurality of atomic layer deposition cycles, each comprising:
supplying a first portion of a reactant into the reaction space such that a laminar flow of the reactant is generated from the upstream periphery to the downstream periphery over substantially the entire portion of a substrate in the reaction space; and
supplying a second portion of the reactant vertically into the reaction space such that the second portion merges with the laminar flow of the reactant at a point downstream of the upstream periphery of the reaction space.

27. The method of claim 26, wherein supplying the first portion comprises supplying the first portion via a first path extending from a reactant source to the point of the reaction space, wherein supplying the second portion comprises supplying the second portion via a second path extending from the reactant source to the point of the reaction space, and wherein the second path is shorter than the first path.

28. The method of claim 26, wherein the first portion is equal to or greater in amount than the second portion.

29. The method of claim 26, wherein supplying the first portion further comprises in sequence: flowing the first portion horizontally and flowing the first portion vertically into the reaction space.

30. A gas flow control guide structure for use in an atomic layer deposition (ALD) reactor, comprising:
a body including a top surface and a bottom surface, the body comprising:
a substantially horizontal channel extending generally in a direction from a generally central portion of the body to at least a portion of an edge of the body; and
at least one through-hole penetrating the body, the through-hole opening through the bottom surface of the body, the through-hole being arranged to distribute a reactant across a dimension extending substantially perpendicular to the direction.

31. The structure of claim 30, wherein the body comprises:
a gas flow control plate having an upper surface and a lower surface, the lower surface defining the bottom surface of the body, the gas flow control plate comprising a first groove on the upper surface,
wherein the first groove extends from a generally central portion of the upper surface of the gas flow control plate to at least a portion of an edge of the upper surface of the gas flow control plate,
wherein the first groove widens as the groove extends from the generally central portion to the at least a portion of the edge, and
wherein the gas flow control plate further comprises at least one through-hole penetrating therethrough, the through-hole extending through the upper surface to the lower surface.

32. The structure of claim 31, wherein the at least one through-hole is positioned within the groove.

33. The structure of claim 31, wherein the gas flow control plate further comprises a trench extending into the upper surface, the trench extending from the groove, and wherein the at least one through-hole is positioned within the trench.

34. The structure of claim 31, wherein the at least one through-hole is positioned outside the groove.
